(19) United States
(12) Patent Application Publication
(10) Pub. No.: US 2012/0299575 A1
(43) Pub. Date: Nov. 29, 2012

(54) LOAD REGULATION CIRCUIT AND LOAD REGULATION DEVICE EMPLOYING THE SAME

(75) Inventor: XIAO-LIAN HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/180,715

(22) Filed: Jul. 12, 2011

(30) Foreign Application Priority Data
May 26, 2011 (CN) 201110138019.9

(51) Int. Cl. G01R 35/00

(52) U.S. Cl. 324/74

(57) ABSTRACT

A load regulation circuit used for calibrating a voltage drop tester includes a voltage control switch, a first resistor group, a power control switch and a second resistor group electrically connected to the first resistor group through the power control switch. When the voltage control switch is switched on to different positions, the first resistor group provides different loads and load voltages for the voltage drop tester. When the power control switch is turned on or off, the first resistor group and the second resistor group provide corresponding loads and load powers for the voltage drop tester to calibrate and correct operating parameter of the voltage drop tester. The load regulation circuit can simulate and replace different electronic device to calibrate the voltage drop tester.

### BACKGROUND

1. Technical Field

The disclosure generally relates to test devices, and more particularly to a load regulation circuit to calibrate a voltage drop test device and a load regulation device employing the same.

2. Description of the Related Art

In use, computers, hosts or other electronic devices are electrically connected to a power supply, when other devices are electrically connected to the power supply, the voltage of the electronic devices may suddenly drop, resulting in the electronic devices shutting down or restarting. Thus, in the production process, a voltage drop test device is needed to detect if the electronic devices can work normally if the voltage drop happens.

Before performing the voltage drop test, the voltage drop test device needs to be calibrated to obtain accurate test results. Thus, the electronic devices electrically connected to the voltage drop test device are implemented as loads. The voltage drop test device provides corresponding operating voltages, such as 110V, 220V and 240V, for the electronic devices according to their rated voltages. However, the voltage drop test device needs to repeatedly connected to and unconnected from different electronic devices, which is time consuming. Hence, a load regulation device is used to replace different electronic devices to calibrate the voltage drop test device.

Therefore, there is room for improvement within the art.

### BRIEF DESCRIPTION OF THE DRAWINGS

Many aspects of a load regulation circuit and load regulation device employing the same can be better understood with reference to the following drawings. The components in the drawings are not necessarily drawn to scale, the emphasis instead being placed upon clearly illustrating the principles of the load regulation circuit and load regulation device employing the same. Moreover, in the drawings, like reference numerals designate corresponding parts throughout the several views. Wherever possible, the same reference numbers are used throughout the drawings to refer to the same or like elements of an embodiment.

FIG. 1 is an assembled view of a load regulation device, according to an embodiment of the disclosure.

FIG. 2 is a schematic and exploded view of the load regulation shown in FIG. 1.

FIG. 3 is a circuit view of a load regulation circuit of the load regulation device of the disclosure.

### DETAILED DESCRIPTION

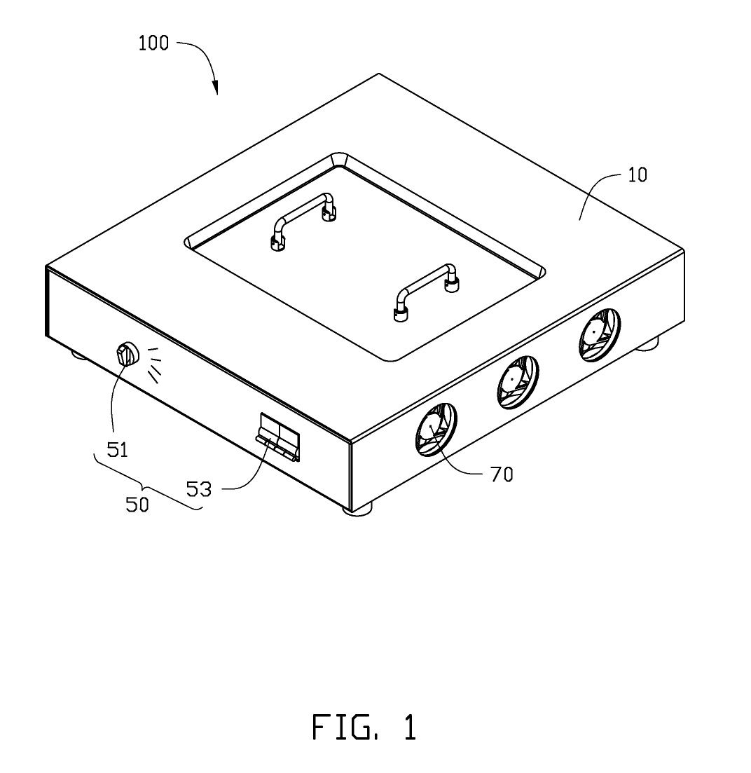

FIG. 1 shows an assembled view of a load regulation device 100, according to an embodiment of the disclosure. The load regulation device 100 is applied to regulate and calibrate a voltage drop tester (not shown). In this embodiment, the load regulation device 100 can provide appropriate loads with corresponding operating voltages and power, for the voltage drop tester to calibrate and correct operating parameters, such as drop voltage and drop time. In this embodiment, the selectable load voltages include 100V, 127V, 200V, and 240V. The selectable load power can be 600 W or 1200 W.

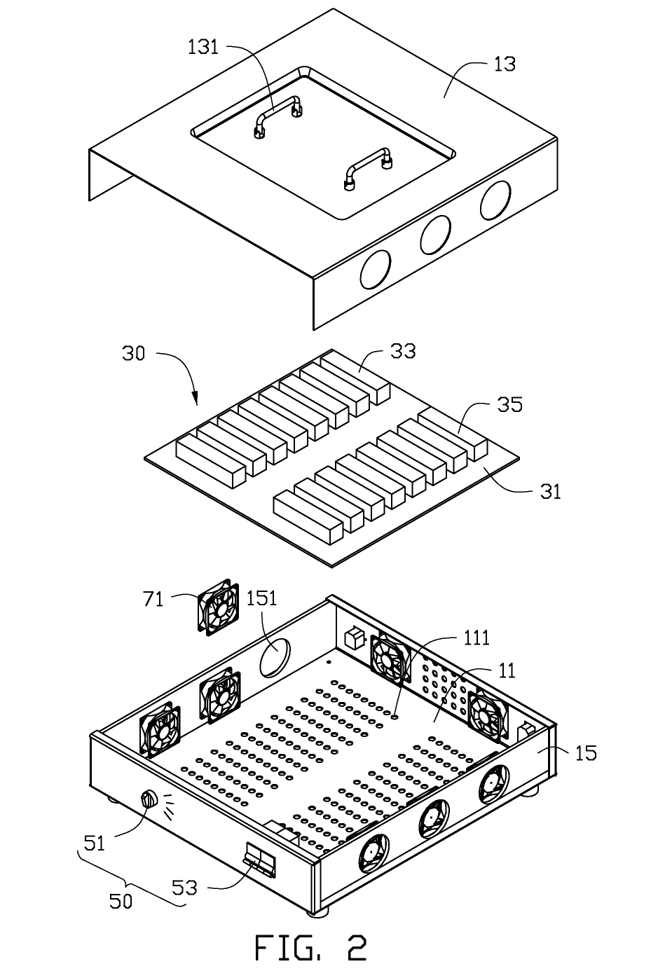

Referring to FIG. 2, the load regulation device 100 includes a housing 10, a circuit assembly 30, a switch assembly 50, and a heat exhausting assembly 70. The circuit assembly 30 is received within the housing 10, and the switch assembly 50 and the heat exhausting assembly 70 are assembled to the housing 10. In this embodiment, the circuit assembly 30 is electrically connected to the voltage drop tester, providing corresponding resistance loads for the voltage drop tester to calibrate and correct the operating parameters.

In this embodiment, the switch assembly 50 includes a voltage control switch 51 and a power control switch 53. The voltage switch 51 controls and switches the load voltages (e.g., 100V, 127V, 200V, or 240V) of the load regulation device 100. The power control switch 53 controls and switches the load powers (e.g., 600 W or 1200 W) of the load regulation device 100 according to feedback results of the voltage drop tester.

The housing 10 is a substantially rectangular box and includes a bottom plate 11, an upper plate 13, and a sidewall 15. The bottom plate 11 is capable of receiving and holding the circuit assembly 30 and defines a plurality of through holes 111 arranged on the bottom plate 11. The through holes 111 are capable of guiding internal heat out of the load regulation device 100. The upper plate 13 is substantially parallel to the bottom plate 11 and includes two handles 131. The handles 131 are fixed on the outer surface of the upper plate 13 to move the upper plate 13. The sidewall 15 connects the bottom plate 11 and the upper plate 13, and defines a plurality of guiding holes 151 for receiving and fixing the heat exhausting assembly 70. The switch assembly 50 is partially located at the sidewall 15.

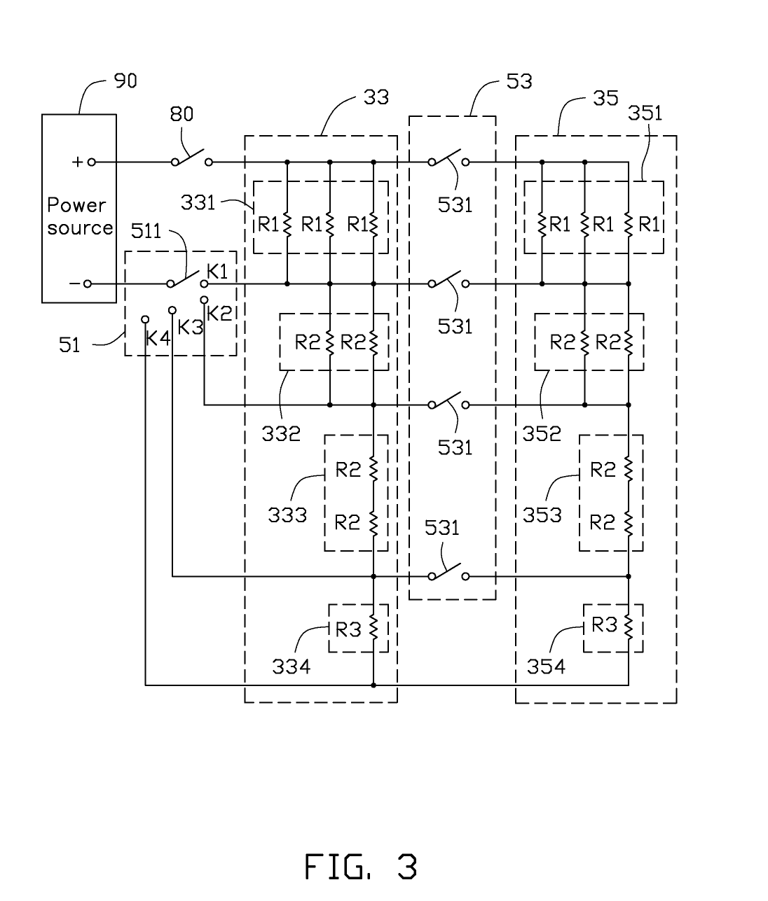

Referring to FIG. 3, the circuit assembly 30 includes a circuit board 31, a first resistor group 33, and a second resistor group 35. In this embodiment, the first resistor group 33 is located at the circuit board 31 and is electrically connected to a power source 90 through the voltage control switch 51. The second resistor group 35 has substantially the same structure and components as the first resistor group 33. The second resistor group 35 is electrically connected to the first resistor group 33 through the power control switch 53 to provide different loads for the voltage drop tester. In this embodiment, the power source 90 is an output voltage of the voltage drop tester, that is, the voltage drop tester provides power supply (e.g., the power source 90) to the load regulation device 100.

In this embodiment, the first resistor group 33 includes a first resistor module 331, a second resistor module 332, a third resistor module 333, and a fourth resistor module 334. The voltage control switch 51 includes a pole 511 and four contacts K1, K2, K3, and K4. The pole 511 is electrically connected to the cathode of the power source 90, the first contact K1 is electrically connected between the first resistor module 331 and the second resistor module 332. The second contact K2 is electrically connected between the second resistor module 332 and the third resistor module 333, the third contact K3 is electrically connected between the third resistor module 333 and one end of the fourth resistor module 334, and the fourth contact K4 is electrically connected to other end of the fourth resistor module 334. The load regulation device 100 further includes a power switch 80 electrically connected between the first resistor module 331 and the anode of the power source 90.

For example, the power switch 80 is turned on, when the pole 511 is switched on to electrically connect to the first contact K1, the first resistor module 331 electrically connects to the power source 90, and provides and outputs a first load voltage, such as 100V. When the pole 511 is switched on to electrically connect to the second contact K2, the first resistor module 331 and the second resistor module 332 are in series and are electrically connected to the power source 90, providing and outputting a second load voltage, such as 127V. When the pole 511 is switched on to electrically connect to the third contact K3, the first resistor module 331, the second resistor module 332 and the third resistor module 333 are in series and are electrically connected to the power source 90, providing and outputting a third load voltage, such as 200V. When the pole 511 is switched on to electrically connect to the fourth contact K4, the first resistor module 331, the second resistor module 332, the third resistor module 333 and the fourth resistor module 334 are in series and are electrically connected to the power source 90. Then provide and output a fourth load voltage, such as 240V, to the voltage drop tester.

In this embodiment, the first resistor module 331 includes three resistors R1 connected in parallel, the second resistor module 332 includes two resistors R2 connected in parallel. The third resistor module 333 includes two resistors R2 connected in series, and the fourth resistor module 334 includes a resistor R3. The resistance of the R1, R2 and R3 is 50 Ohms, 20 Ohms and 30 Ohms, respectively. The first resistor module 331, the second resistor module 332, the third resistor module 333 and the fourth resistor module 334 are electrically connected in series.

The second resistor group 35 is the substantially same as the first resistor group 33, and includes a first resistor module 351, a second resistor module 352, a third resistor module 353, and a fourth resistor module 354 which are electrically connected in series. The first resistor module 351, the second resistor module 352, the third resistor module 353 and the fourth resistor module 354 are respectively and selectably connected to the first resistor module 331. The second resistor module 332, the third resistor module 333 and the fourth resistor module 334 of the first resistor group 33 through the power control switch 53. Thus, when the power control switch 53 is switched on or off, the first resistor group 33 electrically connects to or disconnects from the second resistor group 35.

In this embodiment, the power control switch 53 includes four sub-switches 531 connected between the first resistor group 33 and the second resistor group 35. For example, when the four sub-switches 531 are turned off, the first resistor group 33 is disconnected from the second resistor group 35, the first resistor group 33 of the load regulation device 100 provides and outputs a first load power, such 600 W. When the four sub-switches 531 are turned on, the first resistor group 33 is electrically connected to the second resistor group 35, the load regulation device 100 then provides and outputs a second load power such as 1200 W to the voltage drop tester.

The heat exhausting assembly 70 includes a plurality of fans 71. The fans 71 are located and received within corresponding guiding holes 151 to exhaust heat air out from the load regulation device 100. In this embodiment, an independent power supply or a battery, rather than the power source 90 powers the heat exhausting assembly 70 to avoid the heat exhausting assembly 70 affecting the load voltage and the load power of the load regulation device 100.

Referring to FIGS. 1, 2 and 3, in use, the voltage drop tester is electrically connected to the load regulation device 100, and the power source 90 of the voltage drop tester powers the load regulation device 100. The power switch 80 is turned on. Then different load voltages and load powers are obtained and are generated by switching the voltage control switch 51 and the power control switch 53. For example, when the pole 511 is switched to electrically connect the first contact K1, and the power control switch 53 is turned off, the first resistor module 331 of the first resistor group 33 is electrically connected to the power source 90, and the resistance of the resistor 331 is 50/3 Ohms The load voltage is 100V, then the load power P=(100*100)/(50/3)=600 W. Thus, the load regulation device 100 provides a 100V load voltage and a 600 W load power to the voltage drop tester. When the power control switch 53 is turned on, the first resistor modules 331 and 351 are connected in parallel and are electrically connected to the power source 90, the resistance of the first resistor modules 331 and 351 is 50/6 Ohms Thus, the load regulation device 100 provides a 100V load voltage and a 1200 W load power to the voltage drop tester.

Similarly, when the pole 511 is electrically connected to the second contact K2, and the power control switch 53 is switched off, the load regulation device 100 provides a 127V load voltage and a 600 W load power to the voltage drop tester. When the power control switch 53 is switched on, the load regulation 100 provides a 127V load voltage and a 1200 W load power to the voltage drop tester. When the pole 511 is electrically connected to the second contact K3, and the power control switch 53 is switched off, the load regulation device 100 provides a 200V load voltage and a 600 W load power to the voltage drop tester. When the power control switch 53 is switched on, the load regulation 100 provides a 200V load voltage and a 1200 W load power to the voltage drop tester. When the pole 511 is electrically connected to the second contact K4, and the power control switch 53 is switched off, the load regulation device 100 provides a 240V load voltage and a 600 W load power to the voltage drop tester. When the power control switch 53 is switched on, the load regulation 100 provides a 240V load voltage and a 1200 W load power to the voltage drop tester. Thus, the voltage drop tester is calibrated by viewing the drop voltage and drop time according to the load voltages and the load power of the load regulation device 100 through an oscilloscope.

In summary, the load regulation device 100 of this disclosure, can provide different loads for the voltage drop tester. Hence, the load regulation device 100 can simulate and replace different electronic devices to calibrate the voltage drop tester. Moreover, the load regulation device 100 is easy to operate and has low cost.

In the present specification and claims the word “a” or “an” preceding an element does not exclude the presence of a plurality of such elements. Further, the word “comprising” does not exclude the presence of other elements or steps than those listed.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A load regulation circuit for calibrating a voltage drop tester, the load regulation circuit comprising:
a circuit assembly electrically connected to the voltage drop tester; and
a switch assembly electrically connected to the circuit assembly, wherein the switch assembly is selectably turned on or off, the circuit assembly provides corresponding loads and outputs different load voltages and load powers for the voltage drop tester to calibrate and correct operating parameter of the voltage drop tester.

2. The load regulation circuit as claimed in claim 1, wherein the switch assembly comprises a voltage control switch and a power control switch, the voltage switch controls and switches the load voltages of the circuit assembly, and the power control switch controls and switches the load powers of the circuit assembly based on feedback results of the voltage drop tester.

3. The load regulation circuit as claimed in claim 2, wherein the circuit assembly comprises a first resistor group and a second resistor group, the first resistor group is electrically connected to a power source through the voltage control switch, and the second resistor group is electrically connected to the first resistor group through the power control switch to provide different loads for the voltage drop tester.

4. The load regulation circuit as claimed in claim 3, wherein the first resistor group comprises a first resistor module, a second resistor module, a third resistor module, and a fourth resistor module, the voltage control switch comprises s pole and a first contact, a second contact, a third contact and a fourth contact, the pole is electrically connected to the cathode of the power source, the first contact is electrically connected between the first resistor module and the second resistor module, the second contact is electrically connected between the second resistor module and the third resistor module, the third contact is electrically connected between the third resistor module and one end of the fourth resistor module, and the fourth contact is electrically connected to other end of the fourth resistor module.

5. The load regulation circuit as claimed in claim 4, further comprising a power switch connected between the first resistor module and the power source, wherein the power switch is turned on, when the pole is switched on to connect to the first contact, the first resistor module connects to the power source, and provides a first load voltage, when the pole is switched on to connected to the second contact, the first resistor module and the second resistor module are in series and are connected to the power source and provide a second load voltage.

6. The load regulation circuit as claimed in claim 5, wherein when the pole is switched on to connected to the third contact, the first resistor module the second resistor module and the third resistor module are in series and are connected to the power source and provide a third load voltage, when the pole is turned on to connected to the fourth contact, the first resistor module, the second resistor module, the third resistor module and the fourth resistor module are connected in series to the power source and provide a fourth load voltage to the voltage drop tester.

7. The load regulation circuit as claimed in claim 4, wherein the second resistor group is the substantially same as the first resistor group, the second resistor group comprises a first resistor module, a second resistor module, a third resistor module, and a fourth resistor module electrically connected to the first resistor module, the second resistor module, the third resistor module and the fourth resistor module of the first resistor group through the power control switch, and when the power control switch is switched on or off, the first resistor group electrically connects to or disconnects from the second resistor group.

8. The load regulation circuit as claimed in claim 7, wherein the power control switch comprises four sub-switches connected between the first resistor group and the second resistor group, when the four sub-switches are turned off, the first resistor group is disconnected from the second resistor group, the first resistor group provides and outputs a first load power, when the sub-switches are turned on, the first resistor group is electrically connected to the second resistor group, and provides a second load power to the voltage drop tester.

9. A load regulation circuit for calibrating a voltage drop tester, comprising:
a voltage control switch electrically connected to the voltage drop tester;
a first resistor group electrically connected to the voltage drop tester through the voltage control switch;
a power control switch electrically connected to the first resistor group; and
a second resistor group electrically connected to the first resistor group through the power control switch, wherein when the voltage control switch is switched on to different position, the first resistor group provides different loads and load voltages for the voltage drop tester, when the power control switch is turned on or off, the first resistor group and the second resistor group provide corresponding loads and load powers for the voltage drop tester to calibrate and correct operating parameter of the voltage drop tester.

10. The load regulation circuit as claimed in claim 9, wherein the first resistor group comprises a first resistor module, a second resistor module, a third resistor module, and a fourth resistor module, the voltage control switch comprises s pole and a first contact, a second contact, a third contact and a fourth contact, the pole is electrically connected to the cathode of the power source, the first contact is electrically connected between the first resistor module and the second resistor module, the second contact is electrically connected between the second resistor module and the third resistor module, the third contact is electrically connected between the third resistor module and one end of the fourth resistor module, and the fourth contact is electrically connected to other end of the fourth resistor module.

11. The load regulation circuit as claimed in claim 10, further comprising a power switch connected between the first resistor module and the power source, wherein the power switch is turned on, when the pole is switched on to connect to the first contact, the first resistor module connects to the power source, and provides a first load voltage, when the pole is switched on to connected to the second contact, the first resistor module and the second resistor module are in series and are connected to the power source and provide a second load voltage.

12. The load regulation circuit as claimed in claim 11, wherein when the pole is switched on to connected to the third contact, the first resistor module the second resistor module and the third resistor module are in series and are connected to the power source and provide a third load voltage, when the pole is turned on to connected to the fourth contact, the first resistor module, the second resistor module, the third resistor module and the fourth resistor module are connected in series to the power source and provide a fourth load voltage to the voltage drop tester.

13. The load regulation circuit as claimed in claim 10, wherein the second resistor group is the substantially same as the first resistor group, the second resistor group comprises a first resistor module, a second resistor module, a third resistor module, and a fourth resistor module electrically connected to the first resistor module, the second resistor module, the third resistor module and the fourth resistor module of the first resistor group through the power control switch, and when the power control switch is switched on or off, the first resistor group electrically connects to or disconnects from the second resistor group.

14. The load regulation circuit as claimed in claim 13, wherein the power control switch comprises four sub-switches connected between the first resistor group and the second resistor group, when the four sub-switches are turned off, the first resistor group is disconnected from the second resistor group, the first resistor group provides and outputs a first load power, when the sub-switches are turned on, the first resistor group is electrically connected to the second resistor group, and provides a second load power to the voltage drop tester.

15. A load regulation device for calibrating drop voltage and drop time of a voltage drop tester, the load regulation device comprising:
a housing;
a circuit board received within the housing;
a voltage control switch located on the circuit board and electrically connected to the circuit board and the voltage drop tester;
a first resistor group located on the circuit board and electrically connected to the voltage drop tester through the voltage control switch;
a power control switch located on the circuit board and electrically connected to the first resistor group; and
a second resistor group located on the circuit board and electrically connected to the first resistor group through the power control switch, wherein when the voltage control switch is switched on to different position, the first resistor group provides different loads and voltages for the voltage drop tester, when the power control switch is turned on or off, the first resistor group and the second resistor group provide corresponding loads and powers for the voltage drop tester, and the loads, the voltages and the powers are capable of calibrating and correcting operating parameter of the voltage drop tester.

16. The load regulation device as claimed in claim 15, wherein the first resistor group comprises a first resistor module, a second resistor module, a third resistor module, and a fourth resistor module, the voltage control switch comprises s pole and a first contact, a second contact, a third contact and a fourth contact, the pole is electrically connected to the cathode of the power source, the first contact is electrically connected between the first resistor module and the second resistor module, the second contact is electrically connected between the second resistor module and the third resistor module, the third contact is electrically connected between the third resistor module and one end of the fourth resistor module, and the fourth contact is electrically connected to other end of the fourth resistor module.

17. The load regulation device as claimed in claim 16, further comprising a power switch connected between the first resistor module and the power source, wherein the power switch is turned on, when the pole is switched on to connect to the first contact, the first resistor module connects to the power source, and provides a first load voltage, when the pole is switched on to connected to the second contact, the first resistor module and the second resistor module are in series and are connected to the power source and provide a second load voltage.

18. The load regulation device as claimed in claim 17, wherein when the pole is switched on to connected to the third contact, the first resistor module the second resistor module and the third resistor module are in series and are connected to the power source and provide a third load voltage, when the pole is turned on to connected to the fourth contact, the first resistor module, the second resistor module, the third resistor module and the fourth resistor module are connected in series to the power source and provide a fourth load voltage to the voltage drop tester.

19. The load regulation device as claimed in claim 16, wherein the second resistor group is the substantially same as the first resistor group, the second resistor group comprises a first resistor module, a second resistor module, a third resistor module, and a fourth resistor module electrically connected to the first resistor module, the second resistor module, the third resistor module and the fourth resistor module of the first resistor group through the power control switch, and when the power control switch is switched on or off, the first resistor group electrically connects to or disconnects from the second resistor group.

20. The load regulation device as claimed in claim 19, wherein the power control switch comprises four sub-switches connected between the first resistor group and the second resistor group, when the four sub-switches are turned off, the first resistor group is disconnected from the second resistor group, the first resistor group provides and outputs a first load power, when the sub-switches are turned on, the first resistor group is electrically connected to the second resistor group, and provides a second load power to the voltage drop tester.
